(19) United States
(12) Patent Application Publication
(10) Pub. No.: US 2008/0293248 A1
(43) Pub. Date: Nov. 27, 2008

(54) METHOD OF FORMING AMORPHOUS CARBON FILM AND METHOD OF MANUFACTURING SEMICONDUCTOR DEVICE USING THE SAME

(75) Inventors: Keun Oh Park, Seoul (KR); Byoung Dae An, Suwon-Si (KR); Seung Jun Lee, Yongin-Si (KR)

Correspondence Address: MARGER JOHNSON & MCCOLLOM, P.C., 210 SW MORRISON STREET, SUITE 400, PORTLAND, OR, 97204, US

(73) Assignee: TES CO., LTD., Yongjn-Si (KR)

(21) Appl. No.: 11/839,394

(22) Filed: Aug. 15, 2007

(30) Foreign Application Priority Data
May 22, 2007 (KR) 10-2007-0049730

(51) Int. Cl. H01L 21/311; H05H 1/24

(52) U.S. Cl. 438/694; 427/569; 427/577; 257/E21.247

(57) ABSTRACT

The present invention relates to a method of forming an amorphous carbon film and a method of manufacturing a semiconductor device using the method. An amorphous carbon film is formed on a substrate by vaporizing a liquid hydrocarbon compound, which has chain structure and one double bond, and supplying the compound to a chamber, and ionizing the compound. The amorphous carbon film is used as a hard mask film.

It is possible to easily control characteristics of the amorphous carbon film, such as a deposition rate, an etching selectivity, a refractive index (n), a light absorption coefficient (k) and stress, so as to satisfy user's requirements. In particular, it is possible to lower the refractive index (n) and the light absorption coefficient (k). As a result, it is possible to perform a photolithography process without an antireflection film that prevents the diffuse reflection of a lower material layer.

Further, a small amount of reaction by-product is generated during a deposition process, and it is possible to easily remove reaction by-products that are attached on the inner wall of a chamber. For this reason, it is possible to increase a cycle of a process for cleaning a chamber, and to increase parts changing cycles of a chamber. As a result, it is possible to save time and cost.

### BACKGROUND OF THE INVENTION

1. Field of the Invention

The present invention relates to a method of forming an amorphous carbon film, and more particularly, to a method of forming an amorphous carbon film having a low light absorption coefficient and a wide range of refractive index by using a liquid hydrocarbon compound, and a method of manufacturing a semiconductor device using the method.

2. Description of the Related Art

A semiconductor device includes various elements such as word lines, bit lines, capacitors, and metal wires, which interact with one another. As a degree of integration and a performance of a semiconductor device increase, demand for materials and process technologies for manufacturing the semiconductor device is also increasing. In particular, the increase of the degree of integration is accompanied with a decrease of the size of a semiconductor device, a method of forming fine patterns for various structures on a semiconductor substrate has been studied continuously.

Due to increasing demands for an improved photolithography process to form fine patterns, the wavelength of an exposure light source is gradually decreasing. For example, as the degree of integration of a semiconductor device is increased, KrF laser with a wavelength of 248 nm or ArF laser with a wavelength of 193 nm is used as the exposure light source instead of G-line with a wavelength of 436 nm or i-line with a wavelength of 365 nm. In order to form finer patterns, an X-ray or electron beam may be used as the exposure light source.

When a pattern size is reduced as described above, the thickness of a photosensitive film pattern should be reduced to control the resolution of the pattern. However, when the thickness of the photosensitive film pattern is undesirably thin, the photosensitive film pattern can be etched away ahead of the lower material layer that is thicker than the photosensitive film pattern, whereby a lower material layer pattern can not be formed. Accordingly, a hard mask film such as an oxide film (SiO₂) or a nitride film (Si₃N₄) other than photosensitive film patterns are additionally formed on the lower material layer in order to ensure a process margin during the etching process for forming patterns.

In a highly integrated semiconductor device, i.e., a semiconductor device having a size smaller than 100 nm, the height of the metal wire is increased to compensate for the increase of resistance caused by reduced width of a metal wire and a gap between the metal wires. Further, the width of a poly silicon film, an oxide film, or a nitride film, and a gap between the films are reduced, and the thickness of each film is increased. Accordingly, the thickness of the hard mask film needs to be increased to prevent the hard mask film from being etched away before the material layer is completely etched. As the thickness of the hard mask film is increased, the thickness of the photosensitive film also needs to be increased. When the linewidth is small, however, the photosensitive film pattern collapses during the etching process of the hard mask. Accordingly, it is not possible to pattern the hard mask film and the lower material layer. Further, if the thickness of the hard mask film is increased, productivity of the apparatus per unit time is decreased. Productivity decrease in the subsequent etching process and troubles caused by impurities become more probable as well.

Further, when the hard mask film is formed on a metal layer having an increased thickness, diffused reflection takes place due to a high light absorption coefficient (k) of the hard mask film. As a result, necking and footing occur in the developing process due to the diffused reflection. Necking is a phenomenon in which the width of the lower portion of the photosensitive film pattern is decreased. Footing is a phenomenon in which the width of the lower portion of the photosensitive film is gently increased. If the metal layer is patterned using such a photosensitive film pattern, the cross-sectional area of the pattern is decreased. As the gap between the patterns becomes smaller, the reduction of the cross-sectional area becomes more significant. Further, the reduction of the cross-sectional area increases the resistance of the wire, lowers down the processing speed of the device and damages the reliability of the device by facilitating movement of electrons. Accordingly, an anti-reflection film should be formed additionally to prevent diffused reflection of the hard mask film.

For this reason, an amorphous carbon film is used as a hard mask. In this case, even if the thickness of the amorphous carbon film is small, it is possible to obtain high resolution and to perform an accurate patterning regardless of an etching rate. A hydrocarbon compound such as benzene (C₆H₆) or toluene (C₇H₈), which has a benzene ring or a plurality of double bonds, has been conventionally used to form an amorphous carbon film. When using the above-mentioned materials, however, it is not possible to freely adjust a deposition rate, an etching selectivity, a refractive index (n), a light absorption coefficient (k), and stress characteristics. For example, when using benzene (C₆H₆) or toluene (C₇H₈), deposition rate is high, etching selectivity is low, and much reaction by-products is generated. Due to generation of large amount of reaction by-products, the deposition rate of the amorphous carbon film is reduced and residual particles in the amorphous carbon film increases, whereby the quality and characteristics of the amorphous carbon film deteriorates. Because the reaction by-products are usually stuck to the inner wall of a chamber, a cleaning process should be performed more often, which result in a longer processing time and a higher cost. Meanwhile, the reaction by-products are not easily removed from the chamber in the cleaning process. As a result, the quality of the amorphous carbon film deteriorates and parts changing cycles of a chamber are shortened.

### SUMMARY OF THE INVENTION

The present invention provides a method of forming an amorphous carbon film capable of forming desired patterns without the occurrence of diffused reflection by forming an amorphous carbon film whose refractive index can be finely controllable and light absorption coefficient is low.

Further, the present invention provides a method of forming an amorphous carbon film where a small amount of reaction by-products is generated, a chamber is hardly contaminated, the reaction by-products are easily removed and thus cost and processing time can be saved.

Furthermore, the present invention provides a method of manufacturing a semiconductor device using an amorphous carbon film, wherein the amorphous carbon film is formed by vaporizing a liquid hydrocarbon compound, and a photosensitive film can be accurately patterned without an anti-reflection film by using the amorphous carbon film as a hard mask film.

According to an aspect of the present invention, a method of forming an amorphous carbon film includes loading a substrate into a chamber; and forming an amorphous carbon film on the substrate by vaporizing a chain-structured liquid hydrocarbon compound including one double bond, and supplying the compound to the chamber, and ionizing the compound.

The hydrocarbon compound may include one of hexene (C₆H₁₂), nonene (C₉H₁₈), dodecene (C₁₂H₂₄), pentadecene (C₁₅H₃₀) and combinations thereof.

The hydrocarbon compound may be supplied at a flow rate in a range of 0.3 to 0.8 g/min.

The vaporized hydrocarbon compound may be ionized by applying radio frequency power in a range of 800 to 2000 W to the chamber.

Low frequency power in a range of 150 to 400 W may be further applied to the chamber.

The amorphous carbon film may be formed while a pressure in a range of 4.5 to 8 Torr is maintained in the chamber.

The chamber may include a shower head for injecting the vaporized hydrocarbon compound, and a distance between the shower head and the substrate may be maintained in the range of 250 to 400 mils.

The amorphous carbon film may be formed at a temperature in a range of 300 to 550° C.

The amorphous carbon film may be formed at a deposition rate in a range of 15 to 80 Å/sec.

The amorphous carbon film may contain carbon and hydrogen, and a ratio of carbon to hydrogen may be controlled according to the radio frequency power, the amount of the hydrocarbon compound, the chamber pressure, and the deposition temperature.

The content of hydrogen in the amorphous carbon film may be controlled by further supplying hydrogen or ammonia gas.

The amorphous carbon film may have a refractive index in a range of 1.7 to 2.2 and a light absorption coefficient in a range of 0.1 to 0.5.

An etching selectivity of the amorphous carbon film with respect to an oxide film may be in the range of 1:5 to 1:40, and an etching selectivity of the amorphous carbon film with respect to a nitride film may be in the range of 1:1 to 1:20.

The amorphous carbon film may be formed using inert gas, and the deposition rate and the etching selectivity of the amorphous carbon film may be controlled by using the inert gas.

According to another aspect of the present invention, a method of manufacturing a semiconductor device includes forming a material layer on a substrate on which predetermined structures are formed; loading the substrate, on which the material layer is formed, into a chamber; forming an amorphous carbon film on the substrate by vaporizing a chain-structured liquid hydrocarbon compound including one double bond, and supplying the compound to the chamber, and ionizing the compound; forming photosensitive film patterns on the amorphous carbon film, and etching the amorphous carbon film while using the photosensitive film patterns as an etching mask; and etching the exposed material layer, and removing the amorphous carbon film and the photosensitive film patterns.

The amorphous carbon film may be etched using reactive ion etching.

The amorphous carbon film may be etched using one of CF₄ plasma, C₄F₈ plasma, oxygen (O₂) plasma, ozone (O₃) plasma and combinations thereof.

The amorphous carbon film may be etched by remote plasma system using one of oxygen (O₂), NF₃ and combinations thereof.

### BRIEF DESCRIPTION OF THE DRAWINGS

The above and other features and advantages of the present invention will become more apparent by describing in detail preferred embodiments thereof with reference to the attached drawings in which:

FIG. 1 is a schematic cross-sectional view of an apparatus for depositing an amorphous carbon film according to an embodiment of the present invention;

FIGS. 2A to 2D are graphs illustrating changes in characteristics of the amorphous carbon film according to a first example of the present invention, depending on radio frequency power;

FIGS. 3A to 3D are graphs illustrating changes in characteristics of the amorphous carbon film according to a second example of the present invention, depending on the amount of reaction source to be supplied;

FIGS. 4A to 4D are graphs illustrating changes in characteristics of the amorphous carbon film according to a third example of the present invention, depending on a distance between a shower head and a substrate;

FIGS. 5A and 5B are photographs illustrating a lower portion of a chamber after an amorphous carbon film is formed using toluene (C₇H₈) and ethylbenzene (C₈H₁₀) and a cleaning process is performed;

FIG. 6 is a photograph illustrating the lower portion of the chamber after an amorphous carbon film is formed using hexene (C₆H₁₂) and a cleaning process is performed; and

FIGS. 7A to 7F are cross-sectional views illustrating an exemplary method of manufacturing a semiconductor device using the amorphous carbon film according to the examples of the present invention.

### DESCRIPTION OF THE PREFERRED EMBODIMENTS

Preferred embodiments of the present invention will be described in detail below with reference to accompanying drawings.

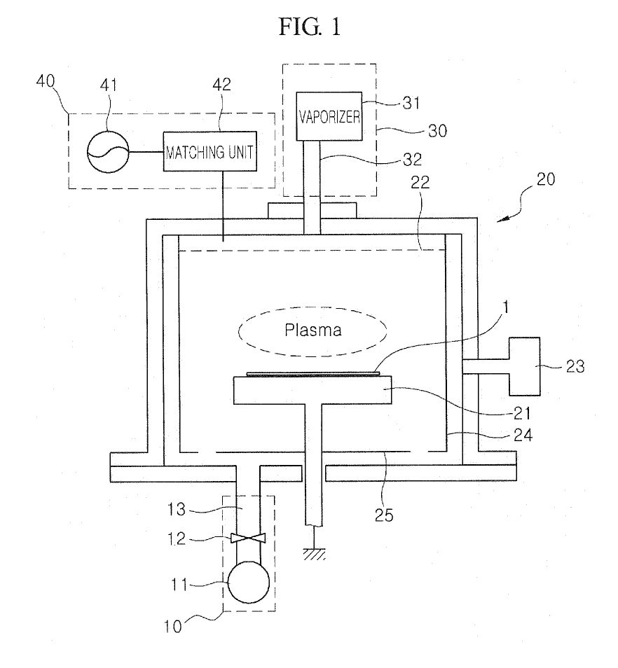

FIG. 1 is a schematic cross-sectional view of a deposition apparatus for forming an amorphous carbon film according to an embodiment of the present invention, that is, a schematic cross-sectional view of a PECVD (Plasma Enhanced Chemical Vapor Deposition) apparatus.

Referring to FIG. 1, a deposition apparatus includes a vacuum unit 10, a chamber 20, a gas supplier 30, and a power supplier 40.

The vacuum unit 10 includes a pump 11 such as a turbo molecular pump, a valve 12, and an exhaust pipe 13. Further, the vacuum unit 10 keeps the inside of the chamber 20 to be in a vacuum state so that deposition is suitably performed. Further, the vacuum unit 10 is used to exhaust unreacted gas remaining in the chamber 20.

The chamber 20 has a rectangular parallelepiped or cylindrical shape corresponding to the shape of the substrate 1, and provides a space for the deposition processes. Further, the chamber includes a substrate supporter 21, a shower head 22, a pressure measuring unit 23, a liner 24, and a pump plat 25. The substrate supporter 21 is disposed at a lower portion in the chamber 20, and the substrate 1 used to form an amorphous carbon film is placed on the substrate supporter. Source gas is supplied to the shower head 22 from the gas supplier 30, and radio frequency power is supplied to the shower head 22 from the power supplier 40. Accordingly, source gas, which is supplied to the shower head from the gas supplier 30 and then injected by the shower head 22, is ionized by the radio frequency power supplied from the power supplier 40, and then deposited on the substrate 1. Further, the shower head 22 is insulated from the inner wall of the chamber 22. The pressure measuring unit 23 measures pressure of the inside of the chamber 20. The pressure measured by the pressure measuring unit 23 is reflected on the control of an opening degree of the valve 12. As a result, it is possible to maintain the pressure of the inside of the chamber 20 at a predetermined pressure. The liner 24 is provided on the inner wall of the chamber 20 in order to prevent the inner wall, which is made of aluminum, of the chamber 20 from being damaged by plasma or to prevent a reactant from being deposited on the inner wall of the chamber 20. It is preferable that the liner be made of a ceramic material. The pump plat 25 allows residual gas to be exhausted uniformly through the exhaust pipe 13 by the pump 11. The pump plat 25 has a shape of a plate having a plurality of holes.

The gas supplier 30 includes a vaporizer 31 and a gas supplying pipe 32. The vaporizer 31 vaporizes liquid phase reaction source to form an amorphous carbon film on the substrate 1. Vaporized reaction source and carrier gas including argon gas are supplied to the chamber 20 through the gas supplying pipe 32.

The power supplier 40 includes a radio frequency generator 41 and a matching unit 42. Further, the power supplier 40 applies radio frequency power to the shower head 22 so that the source gas is ionized and deposited on the substrate 1. The radio frequency generator 41 generates a radio frequency power of 13.56 MHz in a range of 800 to 2000 W.

Meanwhile, the deposition apparatus may include another power supplier (not shown) including a low frequency generator (not shown) and a matching unit (not shown) to generate low frequency power, in addition to the power supplier 40 including the radio frequency generator 41 and the matching unit 42 to generate radio frequency power. The power supplier generating low frequency power, may be connected to the lower portion of the chamber 20, for example, the substrate supporter 21. When the low frequency power is supplied, the linearity of ions of the source gas is improved. As a result, uniformity of an amorphous carbon film deposited on the substrate 1 is improved and a stress of a thin film is reduced, whereby the quality of the thin film is improved. The low frequency power generator generates low frequency power of 400 kHz in a range of 150 to 400 W.

A method of forming an amorphous carbon film, which uses the aforementioned deposition apparatus, according to an embodiment of the present invention will be described below.

First, the substrate 1 on which predetermined structures are formed is placed on the substrate supporter 21 and then loaded into the chamber 20. After the inside of the chamber 20 is evacuated by the vacuum unit 10, the reaction source is vaporized and then injected by the gas supplier 30 and the shower head 22. In this case, in the chamber 20, radio frequency (RF) power is applied to the shower head 12 from the power supplier 40. Plasma is generated in the chamber 20 due to the radio frequency power, and the reaction source is ionized and moves to the substrate 1. Further, low frequency power is further applied to the substrate supporter 21, so that the linearity of ions is improved due to the low frequency power. Accordingly, an amorphous carbon film with improved quality and uniformity is formed on the substrate 1.

In this case, a liquid hydrocarbon compound is vaporized to be used as the reaction source to form the amorphous carbon film. The liquid hydrocarbon compound may be transformed to a gas by vaporization, and further to a plasma state depending on reaction conditions. The hydrocarbon compound used in exemplary embodiments of the present invention is chain-structured, includes one double bond, and consists of carbon atoms and hydrogen atoms. Such hydrocarbon compound includes one selected from the group consisting of hexene (C₆H₁₂), nonene (C₉H₁₈), dodecene (C₁₂H₂₄), pentadecene (C₁₅H₃₀) and combinations thereof, which are represented by Formulas 1 to 4, respectively. A deposition rate, an etching selectivity, a refractive index (n), a light absorption coefficient (k), and stress characteristics of the above-mentioned hydrocarbon compounds can be controlled easily compared to other hydrocarbon compounds. In addition, less amount of reaction by-product is generated when using the above-mentioned hydrocarbon compounds compared to other hydrocarbon compounds, thereby less amount of by-products is stuck to the inner wall of the chamber 20. Accordingly, processes for removing contaminants from the inner wall of the chamber 20 can be simplified.

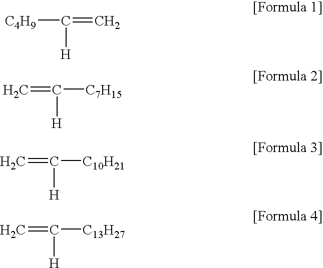

Further, inert gas including argon gas, helium gas, or the like, is used as plasma generating gas and carrier gas to carry the source gas. In this case, the hydrocarbon compound is supplied in a liquid phase at a flow rate in a range of 0.3 to 0.8 g/min. In particular, the argon gas, one of the inert gases used as carrier gas, is used to improve the uniformity of plasma, the uniformity of the thickness and quality of the film of the amorphous carbon film. Furthermore, hydrogen (H₂) gas or ammonia (NH₃) gas may be used to control the concentration of hydrogen in an amorphous carbon film.

In addition, desirable conditions to form an amorphous carbon film include radio frequency power of 13.56 MHz in a range of 800 to 2000 W, chamber pressure in a range of 4.5 to 8 Torr, temperature of 300 to 550° C., and a distance between the substrate and the shower head in a range of 250 to 400 mils. In this case, the amorphous carbon film is formed at a deposition rate in a range of 15 to 80 Å. Further, low frequency power of 400 KHz in a range of 150 to 400 W may be further applied to allow the amorphous carbon film to be uniformly deposited, and to improve the quality of the film by reducing the stress of a thin film.

When the radio frequency power is low, a deposition rate is decreased. As a result, a film is not deposited. When the radio frequency power is high, a deposition rate increases. Accordingly, a film is not densely deposited. Therefore, the quality of the film deteriorates. When the amount of the reaction source to be supplied is small, a deposition rate is decreased. As a result, the film cannot be deposited to have a desired thickness for a desired time. When the amount of the reaction source to be supplied is large, the deposition rate increases. Accordingly, a film is not densely deposited. Therefore, the quality of the film deteriorates and particles are generated. Further, if a distance between the shower head and the substrate is small, arcing occurs. When a distance between the shower head and the substrate is large, the deposition rate is decreased. As a result, the film is not deposited. Furthermore, when pressure is high, particles are generated. When pressure is low, the characteristics of a refractive index and a light absorption coefficient deteriorate. When temperature is low, the quality of a film deteriorates. When temperature is high, the characteristics of a refractive index and a light absorption coefficient deteriorate. Therefore, it is desirable that the conditions to form an amorphous carbon film be adjusted as described above.

Meanwhile, an amorphous carbon film contains hydrogen, and a ratio of carbon to hydrogen can be controlled in a range of 9:1 to 6:4, which can be achieved by controlling the radio frequency power, the amount of the hydrocarbon compound, chamber pressure, and deposition temperature. That is, in order to increase the ratio of hydrogen, radio frequency power and temperature are decreased, chamber pressure is increased, and the amount of the hydrocarbon compound is increased. In contrast, in order to decrease the ratio of hydrogen, radio frequency power and temperature are increased, chamber pressure is decreased, and the amount of the hydrocarbon compound is decreased.

An etching selectivity of the above-mentioned amorphous carbon film with respect to an underlayer is adjusted in the following etching process depending on the ratio of carbon to hydrogen. An etching selectivity of the above-mentioned amorphous carbon film with respect to an oxide film (SiO₂) is in the range of 1:5 to 1:40, and an etching selectivity of the above-mentioned amorphous carbon film with respect to a nitride film (Si₃N₄) is in the range of 1:1 to 1:20.

Further, a refractive index (n) and a light adsorption coefficient (k) of the amorphous carbon film are controlled according to the ratios of carbon to hydrogen. As the ratio of hydrogen is increased, the refractive index (n) and the light absorption coefficient (k) of the amorphous carbon film decrease. For example, the refractive index (n) of the amorphous carbon film can be controlled in a range of 1.7 to 2.2, and the light absorption coefficient (k) of the amorphous carbon film can be controlled in a range of 0.1 to 0.5.

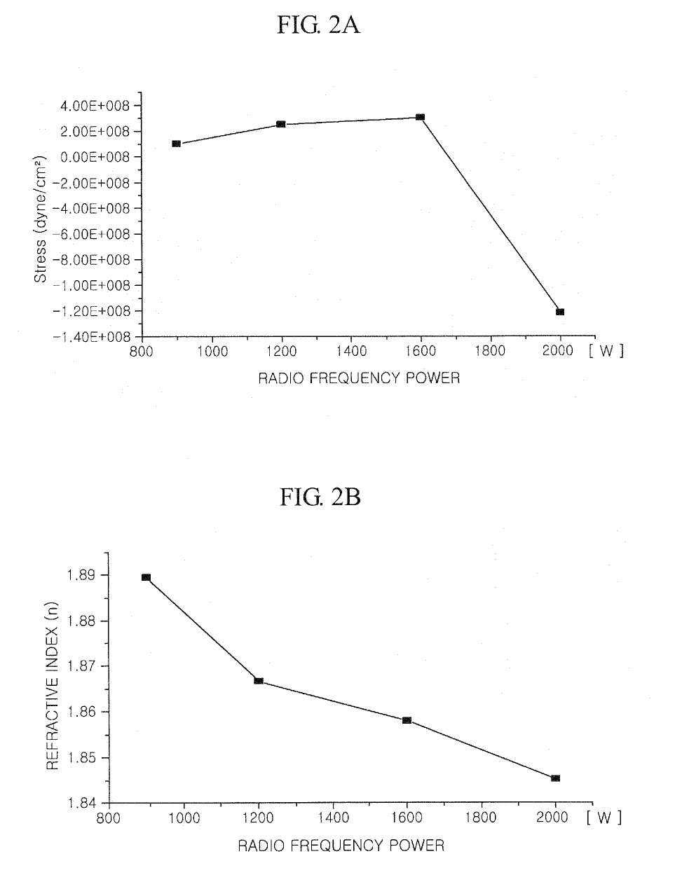

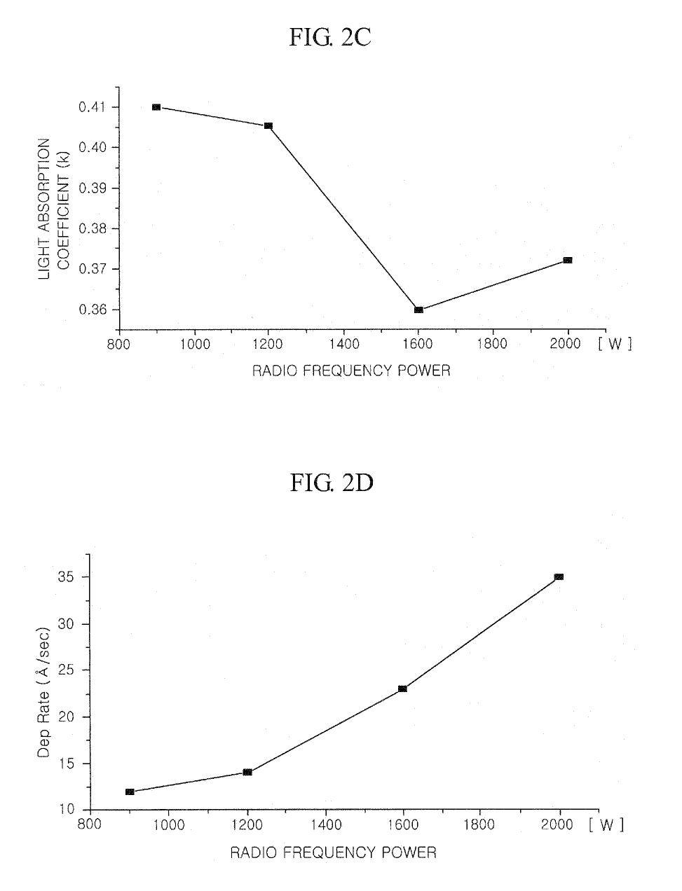

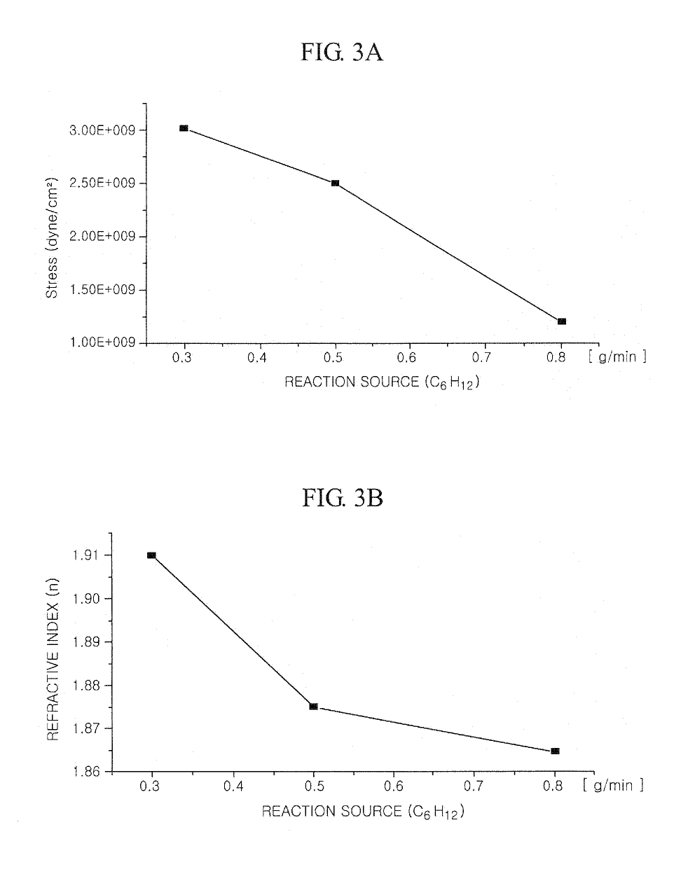

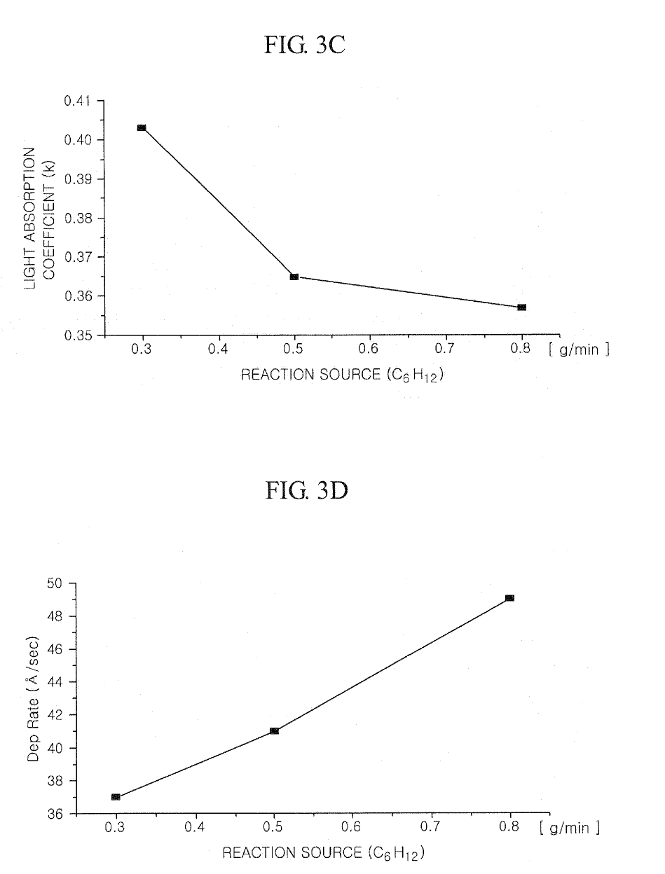

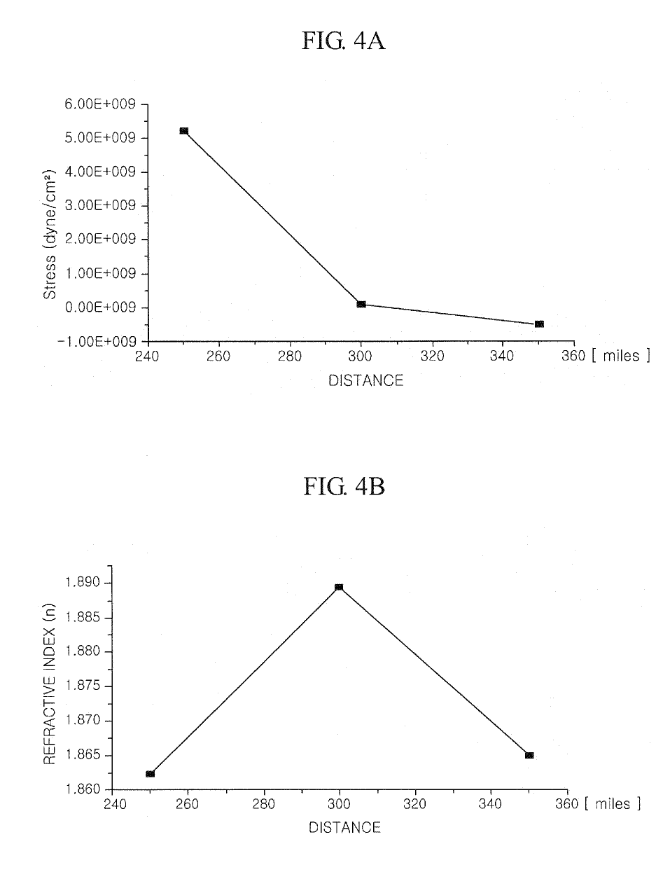

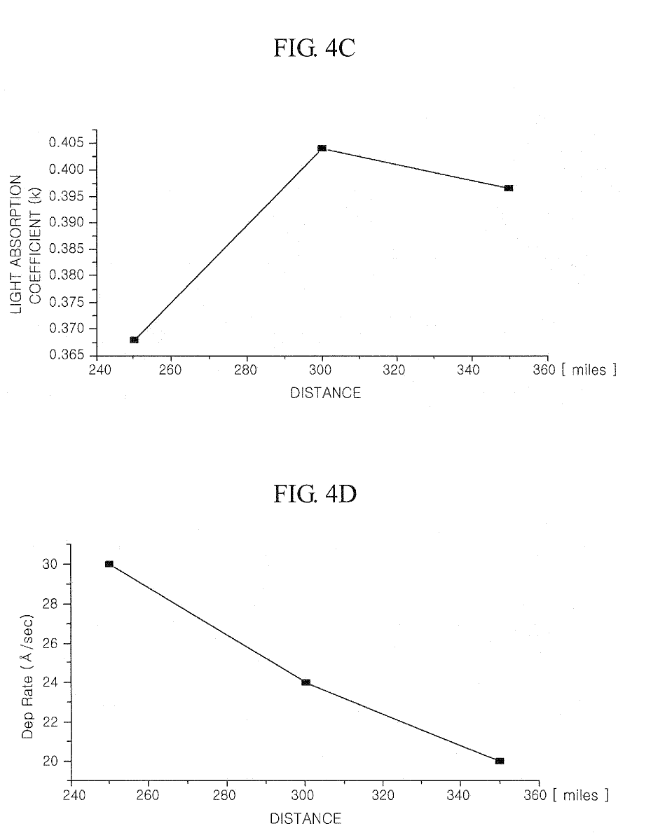

As described above, it is possible to control the stress, refractive index (n), light absorption coefficient (k), and deposition rate of the amorphous carbon film according to the process conditions such as radio frequency power, the amount of the reaction source to be supplied, and the distance between the shower head and the substrate. The characteristics of an amorphous carbon film will be described below by the following examples of the present invention. FIGS. 2A to 2D are graphs illustrating changes in characteristics of the amorphous carbon film according to a first example of the present invention, depending on radio frequency power. FIGS. 3A to 3D are graphs illustrating changes in characteristics of the amorphous carbon film according to a second example of the present invention, depending on the amount of reaction source to be supplied. FIGS. 4A to 4D are graphs illustrating changes in characteristics of the amorphous carbon film according to a third example of the present invention, depending on a distance between a shower head and a substrate. These graphs show changes in characteristics of the amorphous carbon film under optimal conditions.

### FIRST EXAMPLE

### Change in Characteristics of an Amorphous Carbon Film Depending on Radio Frequency Power

In a first example of the present invention, an amorphous carbon film was formed by supplying hexene (C₆H₁₂) at a flow rate of 0.8 g/min, argon at a flow rate of 300 sccm, and helium at a flow rate of 800 sccm at a pressure of 7 Torr and temperature of 550° C. while radio frequency power is changed in a range of 900 to 2000 W. Further, a distance of 350 mils was maintained between the shower head and the substrate. FIGS. 2A to 2D illustrate changes in stress, refractive index (n), light absorption coefficient (k), and deposition rate of the amorphous carbon film, depending on radio frequency power, respectively.

FIG. 2A is a graph illustrating a change in stress of the amorphous carbon film depending on radio frequency power. Referring to FIG. 2A, as radio frequency power increases, stress slightly increases and then significantly decreases after the radio frequency power becomes 1600 W.

FIG. 2B is a graph illustrating a change in refractive index (n) of the amorphous carbon film depending on radio frequency power. Referring to FIG. 2B, as radio frequency power increases, a refractive index (n) is decreased.

FIG. 2C is a graph illustrating a change in light absorption coefficient (k) of the amorphous carbon film depending on the radio frequency power. Referring to FIG. 2C, as the radio frequency power increases, a light absorption coefficient (k) gradually decreases, and then significantly decreases in a range of 1200 to 1600 W. More increase of the radio frequency power above 1600 W, however, results in an increase of the light absorption coefficient (k).

FIG. 2D is a graph illustrating a change in the deposition rate (Å/sec) of the amorphous carbon film depending on the radio frequency power. Referring to FIG. 2D, as the radio frequency power increases, a deposition rate increases.

As understood from the first example of the present invention, stress, a refractive index (n), a light absorption coefficient (k), and a deposition rate can be changed based on radio frequency power. As the radio frequency power increases, the refractive index (n) decreases and the deposition rate increases. Further, as the radio frequency power increases, stress increases and then significantly decreases after the radio frequency power becomes 1600 W. Furthermore, as the radio frequency power increases, the light absorption coefficient (k) significantly decreases and then gradually increases after the radio frequency power becomes 1600 W.

The amorphous carbon film according to the first example of the present invention has a refractive index (n) in a range of 1.84 to 1.89 and a light absorption coefficient (k) in a range of 0.36 to 0.41. Accordingly, the amorphous carbon film is considered to have excellent optical characteristics as a hard mask film or an antireflection film used in the process of manufacturing a semiconductor device.

### SECOND EXAMPLE

### Change in Characteristics of an Amorphous Carbon Film Depending on the Amount of Reaction Source to be Supplied

In a second example of the present invention, an amorphous carbon film was formed by supplying hexene (C₆H₁₂) at a flow rate in the range of 0.3 to 0.8 g/min, argon at a flow rate of 300 sccm, and helium at a flow rate of 200 sccm at a pressure of 7 Torr and temperature of 550° C. while the radio frequency power of 1600 W is applied. Further, a distance of 320 mils was maintained between the shower head and the substrate. In this case, FIGS. 3A to 3D illustrate changes in stress, refractive index (n), light absorption coefficient (k), and deposition rate of the amorphous carbon film, depending on the amount of reaction source to be supplied, respectively.

FIG. 3A is a graph illustrating a change in stress of the amorphous carbon film depending on the amount of reaction source to be supplied. Referring to FIG. 3A, as the amount of reaction source to be supplied increases, stress decreases.

FIG. 3B is a graph illustrating a change in refractive index (n) of the amorphous carbon film depending on the amount of reaction source to be supplied. Referring to FIG. 3B, as the amount of reaction source to be supplied increases, a refractive index (n) decreases.

FIG. 3C is a graph illustrating a change in light absorption coefficient (k) of the amorphous carbon film depending on the amount of reaction source to be supplied. Referring to FIG. 3C, as the amount of reaction source to be supplied increases, a light absorption coefficient (k) decreases.

FIG. 3D is a graph illustrating a change in deposition rate (Å/sec) of the amorphous carbon film depending on the amount of reaction source to be supplied. Referring to FIG. 3D, as the amount of reaction source to be supplied increases, a deposition rate increases.

Accordingly, as understood from the second example of the present invention, stress, a refractive index (n), a light absorption coefficient (k), and a deposition rate can be changed depending on the amount of reaction source to be supplied. As the radio frequency power increases, the refractive index (n) decreases and the deposition rate increases. Further, as the amount of reaction source to be supplied increases, the stress, the refractive index (n), and the light absorption coefficient (k) decrease and the deposition rate increases.

The amorphous carbon film according to the second example of the present invention has a refractive index (n) in the range of 1.86 to 1.91 and a light absorption coefficient (k) in the range of 0.36 to 0.41. Accordingly, the amorphous carbon film is considered to have excellent optical characteristics as a hard mask film or an antireflection film used in the process of manufacturing a semiconductor device.

### THIRD EXAMPLE

### Change in Characteristics of an Amorphous Carbon Film Depending on a Distance Between the Shower Head and the Substrate

In a third example of the present invention, an amorphous carbon film was formed by supplying hexene (C₆H₁₂) at a flow rate of 0.8 g/min, argon at a flow rate of 300 sccm, and helium at a flow rate of 800 sccm at a pressure of 7 Torr and temperature of 550° C. while radio frequency power of 1600 W is applied. Further, a distance between the shower head and the substrate was changed in the range of 250 to 350 mils. In this case, FIGS. 4A to 4D illustrate changes in stress, refractive index (n), light absorption coefficient (k), and deposition rate of the amorphous carbon film, depending on a distance between the shower head and the substrate, respectively.

FIG. 4A is a graph illustrating a change in stress of the amorphous carbon film depending on a distance between the shower head and the substrate. Referring to FIG. 3A, as the distance between the shower head and the substrate becomes large, the stress decreases. Positive (+) stress is a tensile stress and negative (−) stress is a compressive stress. As the distance between the shower head and the substrate becomes large, the stress shifts from tensile stress to compressive stress.

FIG. 4B is a graph illustrating a change in refractive index (n) of the amorphous carbon film depending on a distance between the shower head and the substrate. Referring to FIG. 4B, as the distance between the shower head and the substrate becomes large, a refractive index (n) increases and then decreases after the distance becomes 300 mils.

FIG. 4C is a graph illustrating a change in light absorption coefficient (k) of the amorphous carbon film depending on a distance between the shower head and the substrate. Referring to FIG. 4C, as the distance between the shower head and the substrate increases, a light absorption coefficient (k) significantly increases and then gradually decreases after the distance becomes 300 mils.

FIG. 4D a graph illustrating a change in deposition rate (Å/sec) of the amorphous carbon film depending on a distance between the shower head and the substrate. Referring to FIG. 4D, as the distance between the shower head and the substrate becomes large, a deposition rate decreases.

As understood from the third example of the present invention, stress, a refractive index (n), a light absorption coefficient (k), and a deposition rate can be changed depending on the distance between the shower head and the substrate. As the distance between the shower head and the substrate becomes large, stress and the deposition rate decrease. Further, as the distance between the shower head and the substrate becomes large, the refractive index (n) increases and then decreases after the distance becomes 300 mils. Furthermore, as the distance between the shower head and the substrate increases, the light absorption coefficient (k) significantly increases and then gradually decreases after the distance becomes 300 mils.

The amorphous carbon film according to the third example of the present invention has a refractive index (n) in a range of 1.86 to 1.89 and a light absorption coefficient (k) in a range of 0.36 to 0.41. Accordingly, the amorphous carbon film is considered to have excellent optical characteristics as a hard mask film or an antireflection film used in the process of manufacturing a semiconductor device.

The characteristics of the amorphous carbon film formed using hexene (C₆H₁₂) under various process conditions have been described in the above-mentioned examples. However, an amorphous carbon film having various characteristics may be formed using nonene (C₉H₁₈), dodecene (C₁₂H₂₄), or pentadecene (C₁₅H₃₀) under various process conditions. Furthermore, one or more of them may be mixed to be used to form an amorphous carbon film.

An amorphous carbon film which is formed using nonene (C₉H₁₈), dodecene (C₁₂H₂₄), or pentadecene (C₁₅H₃₀) other than hexene (C₆H₁₂) according to an example of the present invention also has a refractive index (n) in a range of 1.7 to 2.2, preferably 1.85 to 1.88, and a light absorption coefficient (k) in a range of 0.1 to 0.5, preferably 0.36 to 0.4.

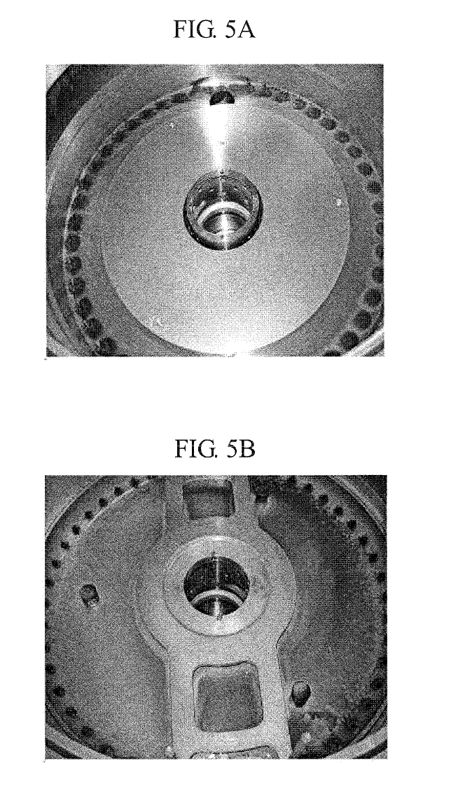

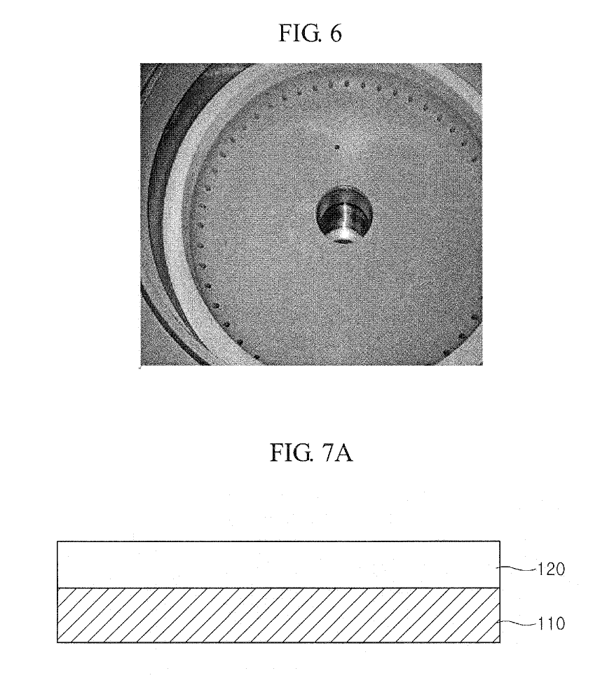

An amorphous carbon film formed using a hydrocarbon compound, which has chain structure and one double bond, generates less amount of reaction by-products compared to other hydrocarbon compounds as described above, and the reaction by-products stuck to the inner wall of the chamber is easily removed. That is, when an amorphous carbon film is formed using ethylbenzene (C₈H₁₀) or toluene (C₇H₈) having a benzene ring, reaction by-products is generated a lot and stuck to the inner wall of the chamber. Further, even though a cleaning process is performed, the reaction by-products are not easily removed. FIGS. 5A and 5B show the residues inside the chamber. However, when an amorphous carbon film is formed using hexene (C₆H₁₂) that has chain structure and one double bond, less amount of reaction by-products is generated. Since the reaction by-products are easily removed by a cleaning process, residues can be hardly shown in FIG. 6.

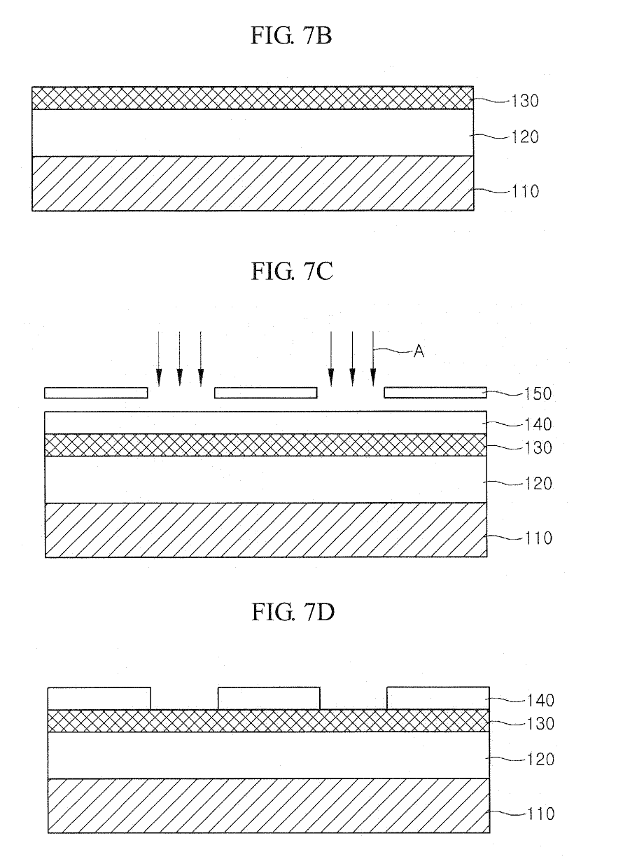

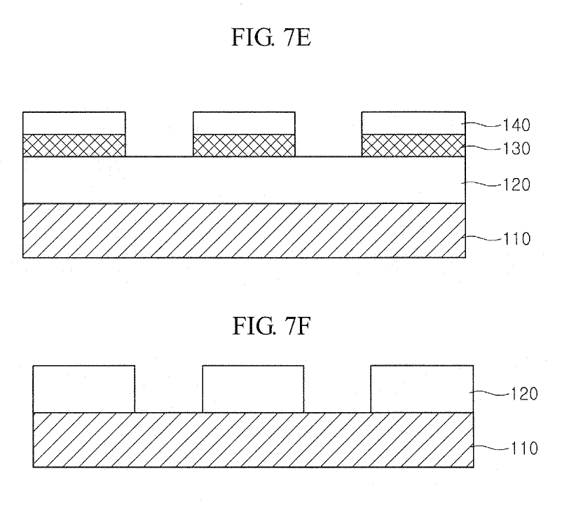

The amorphous carbon film formed using the above-mentioned method may be used as a hard mask in the method of manufacturing a semiconductor device. FIGS. 7A to 7F are cross-sectional views sequentially illustrating a method of manufacturing a semiconductor device using the above-mentioned amorphous carbon film. The amorphous carbon film according to the example of the present invention has a low light absorption coefficient. Accordingly, it is possible to accurately pattern a photosensitive film without a separate antireflection film.

First, as shown in FIG. 7A, a material layer 120, on which patterns are to be formed, is formed on a semiconductor substrate 110. In this case, the semiconductor substrate 110 may be a substrate on which predetermined structures such as a transistor, a capacitor, and a plurality of metal wires are formed to manufacture a semiconductor device. Further, the material layer 120 may be a thin metal film used to form the metal wires, or may be a silicon dioxide film or a silicon nitride film that is used as an interlayer insulating film. Furthermore, the material layer 120 may be a single layer, or may be a laminated layer in which a plurality of films is laminated.

Then, as shown in FIG. 7B, an amorphous carbon film 130 is formed on the material layer 120 by using the above-mentioned method. That is, plasma is generated from carrier gas that includes argon gas and hydrocarbon compound gas including at least one of hexene (C₆H₁₂), nonene (C₉H₁₈), dodecene (C₁₂H₂₄), and pentadecene (C₁₅H₃₀), by using radio frequency power of 13.56 MHz in a range of 800 to 2000 W, in order to ionize the reaction source. As a result, the amorphous carbon film 130 is formed on the material layer 120. In this case, in the chamber, a pressure in the range of 4.5 to 8 Torr, a temperature in the range of 300 to 550° C., and a distance in the range of 250 to 400 mils is maintained between the substrate and the shower head and the amorphous carbon film is formed to have a thickness in the range of 15 to 80 Å. In addition, low frequency power of 400 MHz in a range of 150 to 400 W, may be further applied to the chamber. The amorphous carbon film 130, which is formed as described above, has a high etching selectivity with respect to the material layer 120, and functions as a hard mask film having a low light absorption coefficient (k).

After that, as shown in FIG. 7C, a photosensitive film 140 is formed on the amorphous carbon film 130. Then, for example, ArF laser A is radiated onto the photosensitive film through a mask 150 having predetermined patterns so as to expose the photosensitive film 140. Further, as shown in FIG. 7D, exposed portions of the photosensitive film 140 are developed using a developer.

Subsequently, as shown in FIG. 7E, while the patterned photosensitive film 140 is used as an etching mask, the amorphous carbon film 130 is etched. In this case, the amorphous carbon film 130 is etched using RF plasma or reactive ion etching (RIE). Further, one of CF₄ plasma, C₄F₈ plasma, oxygen (O₂) plasma, ozone (O₃) plasma and combinations thereof may be used to etch the amorphous carbon film 130. Furthermore, the amorphous carbon film 130 may be etched by mixing oxygen and NF₃ and using a remote plasma system.

Next, as shown in FIG. 7F, while the photosensitive film 140 and the amorphous carbon film 130 are used as etching masks, the material layer 120 is etched. In this case, the material layer 120 may be etched by various methods depending on the material of the material layer 120. Then, the photosensitive film 140 and the amorphous carbon film 130 are removed to complete the formation of patterns using the material layer 120.

The amorphous carbon film may be used as a hard mask film in various photo and etching processes of the method of manufacturing a semiconductor device other than the above-mentioned example. For example, the amorphous carbon film may be used as a hard mask film in a damascene process.

Although the invention has been described with reference to the accompanying drawings and the preferred examples, the invention is not limited thereto, but is defined by the appended claims. Therefore, it should be noted that various changes and modifications could be made by those skilled in the art without departing from the technical spirit of the appended claims.

As described above, according to the example of the present invention, an amorphous carbon film is formed using source gas. The source gas is obtained by vaporizing chain-structured hydrocarbon compound having one double bond. The hydrocarbon compound includes one of hexene, nonene, dodecene, pentadecene and combinations thereof in liquid phase.

Characteristics of the amorphous carbon film formed as described above, such as a deposition rate, an etching selectivity, a refractive index (n), a light absorption coefficient (k) and stress, can be controlled easily to satisfy user's requirements. In particular, it is possible to control accurately a refractive index (n) and a light absorption coefficient (k) in a desired range, and to lower the refractive index and the light absorption coefficient. As a result, it is possible to perform a photolithography process without an antireflection film that prevents the diffuse reflection of a lower material layer.

Further, a small amount of reaction by-product is generated, and the reaction by-product stuck to the inner wall of a chamber can be easily removed. Thereby cleaning cycle and parts changing cycle become longer, which saves time and cost.

In addition, the linearity of ions is improved by applying low frequency power. For this reason, it is possible to suppress overhang occurring when an amorphous carbon film is formed on a stepped portion of an element, which improves step coverage. Therefore, it is possible to prevent undesired regions from being etched.

What is claimed is:

1. A method of forming an amorphous carbon film, the method comprising:
loading a substrate into a chamber; and
forming an amorphous carbon film on the substrate by vaporizing a chain-structured liquid hydrocarbon compound including one double bond, supplying the compound to the chamber, and ionizing the compound.

2. The method of claim 1, wherein the hydrocarbon compound comprises one of hexene (C₆H₁₂), nonene (C₉H₁₈), dodecene (Cl₂H₂₄), pentadecene (C₁₅H₃₀) and combinations thereof.

3. The method of claim 1, wherein the hydrocarbon compound is supplied at a flow rate in a range of 0.3 to 0.8 g/min.

4. The method of claim 1, wherein the vaporized hydrocarbon compound is ionized by applying radio frequency power in a range of 800 to 2000 W to the chamber.

5. The method of claim 1, wherein low frequency power in a range of 150 to 400 W is further applied to the chamber.

6. The method of claim 1, wherein the amorphous carbon film is formed while a pressure in a range of 4.5 to 8 Torr is maintained in the chamber.

7. The method of claim 1, wherein the chamber includes a shower head for injecting the vaporized hydrocarbon compound, and
a distance between the shower head and the substrate is maintained in a range of 250 to 400 mils.

8. The method of claim 1, wherein the amorphous carbon film is formed at a temperature in a range of 300 to 550° C.

9. The method of claim 1, wherein the amorphous carbon film is formed at a deposition rate in a range of 15 to 80 Å/sec.

10. The method of claim 1, wherein the amorphous carbon film comprises carbon and hydrogen, and
a ratio of carbon to hydrogen is controlled according to the radio frequency power, the amount of the hydrocarbon compound, the chamber pressure, and the deposition temperature.

11. The method of claim 10, wherein the content of hydrogen in the amorphous carbon film is controlled by further supplying hydrogen or ammonia gas.

12. The method of claim 1, wherein the amorphous carbon film has a refractive index in a range of 1.7 to 2.2 and a light absorption coefficient in a range of 0.1 to 0.5.

13. The method of claim 1, wherein an etching selectivity of the amorphous carbon film with respect to an oxide film is in the range of 1:5 to 1:40, and
an etching selectivity of the amorphous carbon film with respect to a nitride film is in the range of 1:1 to 1:20.

14. The method of claim 1, wherein the amorphous carbon film is formed using inert gas, and
the deposition rate and the etching selectivity of the amorphous carbon film are controlled by using the inert gas.

15. A method of manufacturing a semiconductor device, the method comprising:
forming a material layer on a substrate on which predetermined structures are formed;
loading the substrate, on which the material layer is formed, into a chamber;
forming an amorphous carbon film on the substrate by vaporizing a chain-structured liquid hydrocarbon compound including one double bond, and supplying the compound to the chamber, and ionizing the compound;
forming photosensitive film patterns on the amorphous carbon film, and etching the amorphous carbon film while using the photosensitive film patterns as an etching mask; and
etching the exposed material layer, and removing the amorphous carbon film and the photosensitive film patterns.

16. The method of claim 15, wherein the amorphous carbon film is etched using reactive ion etching.

17. The method of claim 15, wherein the amorphous carbon film is etched using one of CF₄ plasma, C₄F₈ plasma, oxygen (O₂) plasma, ozone (O₃) plasma and combinations thereof.

18. The method of claim 15, wherein the amorphous carbon film is etched by remote plasma system using one of oxygen (O₂), NF₃ and combinations thereof.
